(19) United States
(12) Patent Application Publication
(10) Pub. No.: US 2026/0101782 A1
(43) Pub. Date: Apr. 9, 2026

(54) SEMICONDUCTOR PACKAGES AND METHODS OF FORMATION

(71) Applicant: Taiwan Semiconductor Manufacturing Company, Ltd., Hsinchu (TW)

(72) Inventors: Chieh-Ming CHANG, New Taipei City (TW); Po-Chen LAI, Hsinchu (TW); Ming-Chih YEW, Hsinchu City (TW); Kuo-Chin CHANG, Chiayi City (TW); Kathy Wei YAN, Hsinchu (TW)

(21) Appl. No.: 18/910,402

(22) Filed: Oct. 9, 2024

(51) Int. Cl. H01L 23/538; H01L 21/48; H01L 23/00; H01L 25/065

(52) U.S. Cl. CPC H10W 70/65; H10W 42/121; H10W 70/05; H10W 70/611; H10W 90/401; H10W 90/00

(57) ABSTRACT

A package substrate of a semiconductor package is formed to include bottom conductive pads between package connection pads and conductive structures of the package substrate, where the bottom conductive pads are oblong in a direction along a radial axis through a center of the semiconductor package. The oblong shape and the radial orientation of the bottom conductive pads increase the stiffness of the package substrate, which enables the package substrate to resist deformation that might otherwise occur due to the stresses induced in the package substrate. In this way, the oblong shape and the orientation of the bottom conductive pads reduce the likelihood of cracking and/or delamination in the package substrate that might otherwise be caused by the stresses in the package substrate, which may reduce the likelihood of failure of the semiconductor package and/or may increase the reliability and longevity of the semiconductor package.

### BACKGROUND

A semiconductor die package may include one or more integrated circuit (IC) dies that are bonded to an interposer. Examples of IC dies include a system-on-chip (SoC) IC die, a dynamic random access memory (DRAM) IC die, a logic IC die, and/or a high bandwidth memory (HBM) IC die, among other examples. An interposer may be used to redistribute contact areas from the IC dies to a larger area of the interposer. An interposer may enable three-dimensional (3D) packaging and/or other advanced semiconductor packaging techniques.

A semiconductor package may include one or more semiconductor die packages that are bonded to a package substrate. The semiconductor die packages may be electrically interconnected through one or more redistribution structures of the package substrate. This enables the semiconductor package to include semiconductor die packages that provide different functionality, such as memory, processing, communication, and/or input/output (I/O), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of an example semiconductor package described herein.

FIG. 2 is a diagram of an example of a semiconductor die package described herein.

FIGS. 3A-3L are diagrams of an example implementation of forming a semiconductor package described herein.

FIGS. 4A-4C are diagrams of an example implementation of the semiconductor package.

FIGS. 5A-5C are diagrams of examples of bottom conductive pads that may be included in a redistribution structure of a package substrate of a semiconductor package described herein.

FIG. 6 is a flowchart of an example process associated with forming a semiconductor package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor die package may be disposed on a package substrate of a semiconductor package (e.g., a chip on wafer on substrate (CoWoS) package, an integrated fanout on substrate (InFO_oS) package, an integrated fanout system-on-integrated substrate (InFO_SoIS) package). The package substrate may include one or more redistribution structures (e.g., redistribution layer (RDL) structures) that each include an insulator layer and a plurality of layers of conductive structures disposed in the insulator layer. At the bottom of the package substrate, package connection structures (e.g., ball grid array (BGA) balls, pin grid array (PGA) pins) may be attached to package connection pads of the package substrate. The package connection pads (e.g., BGA pads, PGA pads) may be electrically connected to the conductive structures of the package substrate through a layer of bottom conductive pads in the package substrate.

In some cases, stresses induced in the semiconductor package may cause cracking and/or delamination in the package substrate around the package connection pads. The stresses may be induced, for example, due to bending in a stiffener structure (e.g., a stiffener ring) around the semiconductor package and/or due to mismatches in thermal expansion and/or contraction coefficients of materials in the package substrate. The stresses around the package connection pads of the package substrate may cause cracking and/or delamination in the package substrate around the package connection pads, which can lead to failure of the semiconductor package (e.g., in the form of broken electrical connections) and/or reduced reliability and/or longevity of the semiconductor package.

In some implementations described herein, a package substrate of a semiconductor package is formed to include bottom conductive pads between package connection pads and conductive structures of the package substrate, where the bottom conductive pads are oblong in a direction along a radial axis through a center of the semiconductor package. In other words, a major axis of a bottom conductive pad is aligned with a line between the center of the bottom conductive pad and the center of the semiconductor package, and a minor axis of the bottom conductive pad is approximately perpendicular to the line between the center of the semiconductor package and the center of the bottom conductive pad. The bottom conductive pad may have an oval top view shape, an elliptical top view shape, an obround top view shape, and/or another (standard or non-standard) oblong top view shape. In some implementations, similarly shaped bottom conductive pads may be arranged around a semiconductor die package of the semiconductor package such that the bottom conductive pads are located laterally between the semiconductor die package and a stiffener structure of the semiconductor package.

The oblong shape and the radial orientation of the bottom conductive pads increase the stiffness of the package substrate, which enables the package substrate to resist deformation that might otherwise occur due to the stresses induced in the package substrate. In this way, the oblong shape and the orientation of the bottom conductive pads reduce the likelihood of cracking and/or delamination in the package substrate that might otherwise be caused by the stresses in the package substrate. Thus, the oblong shape and the orientation of the bottom conductive pads may reduce the likelihood of failure of the semiconductor package and/or may increase the reliability and longevity of the semiconductor package.

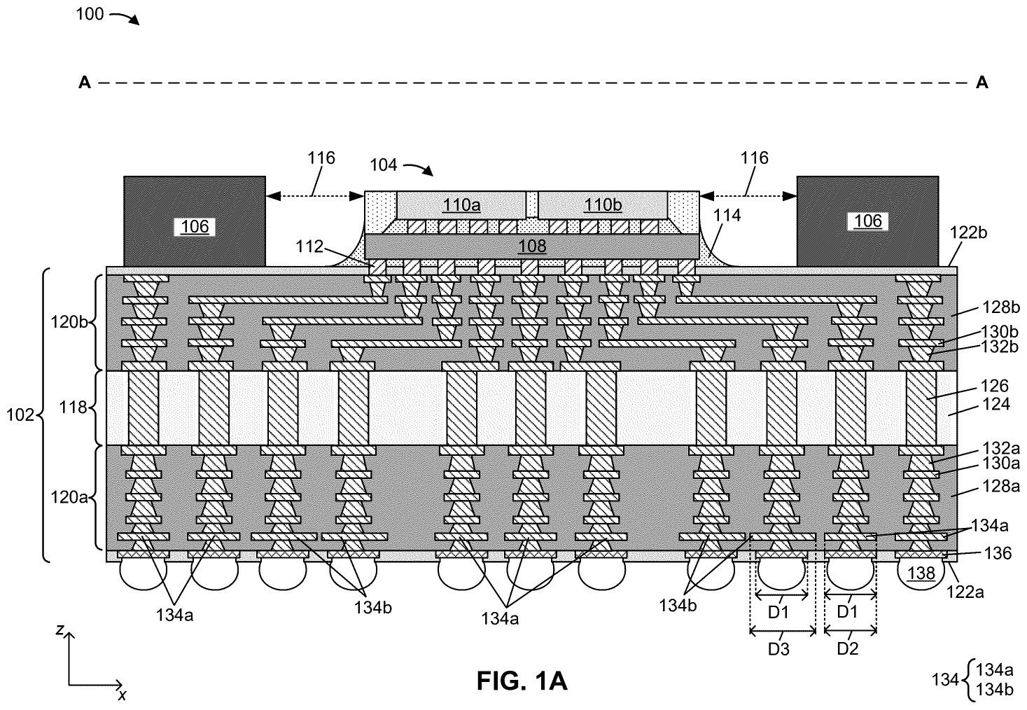

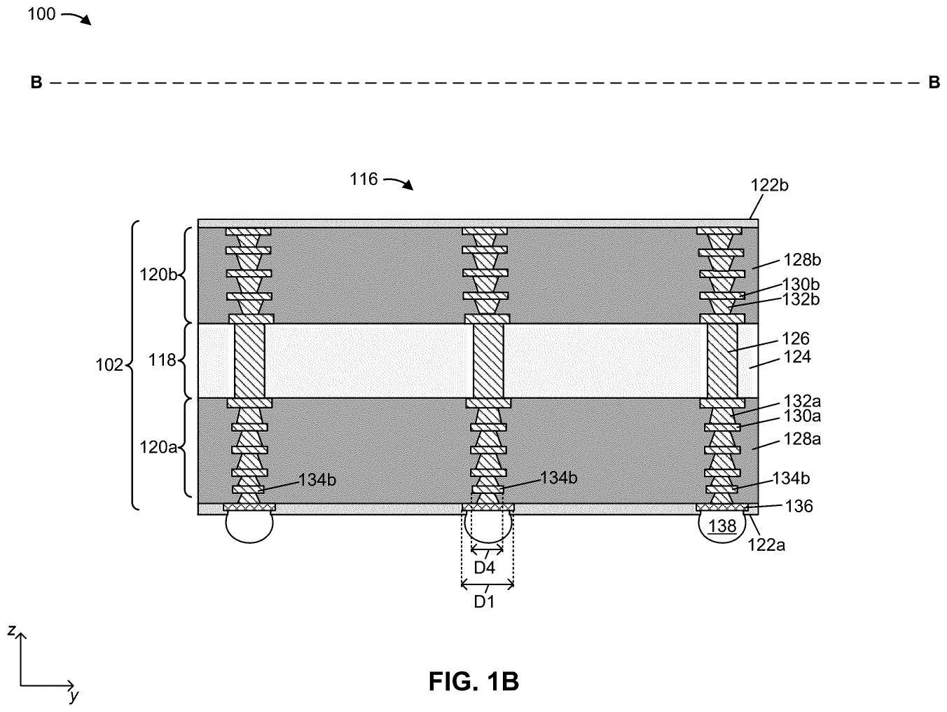

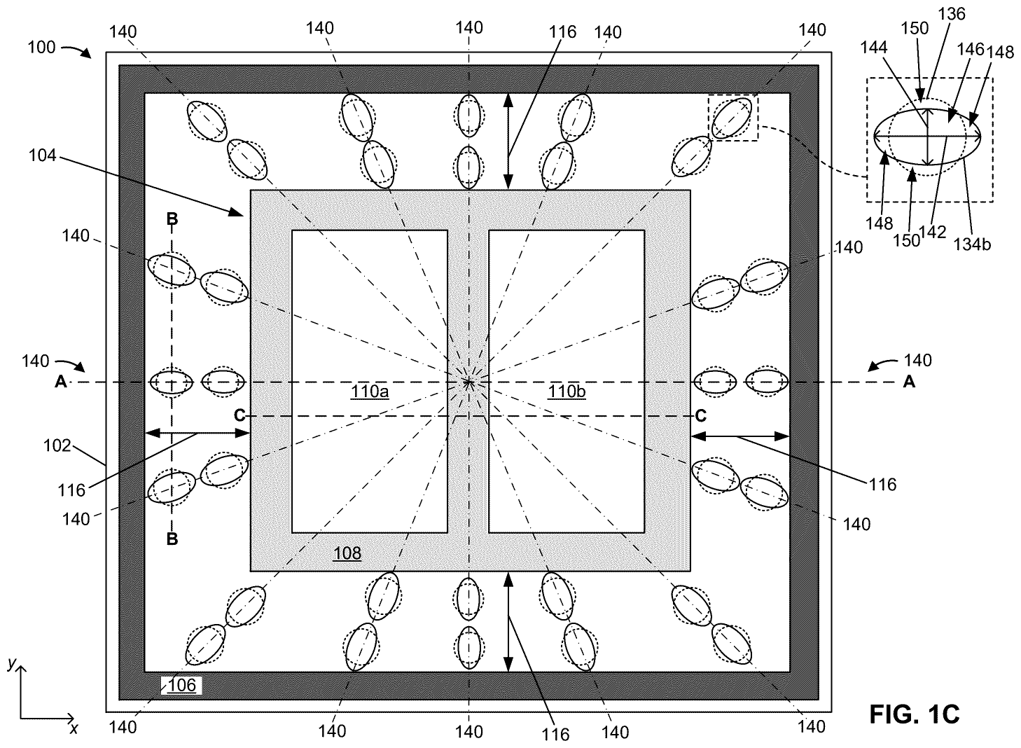

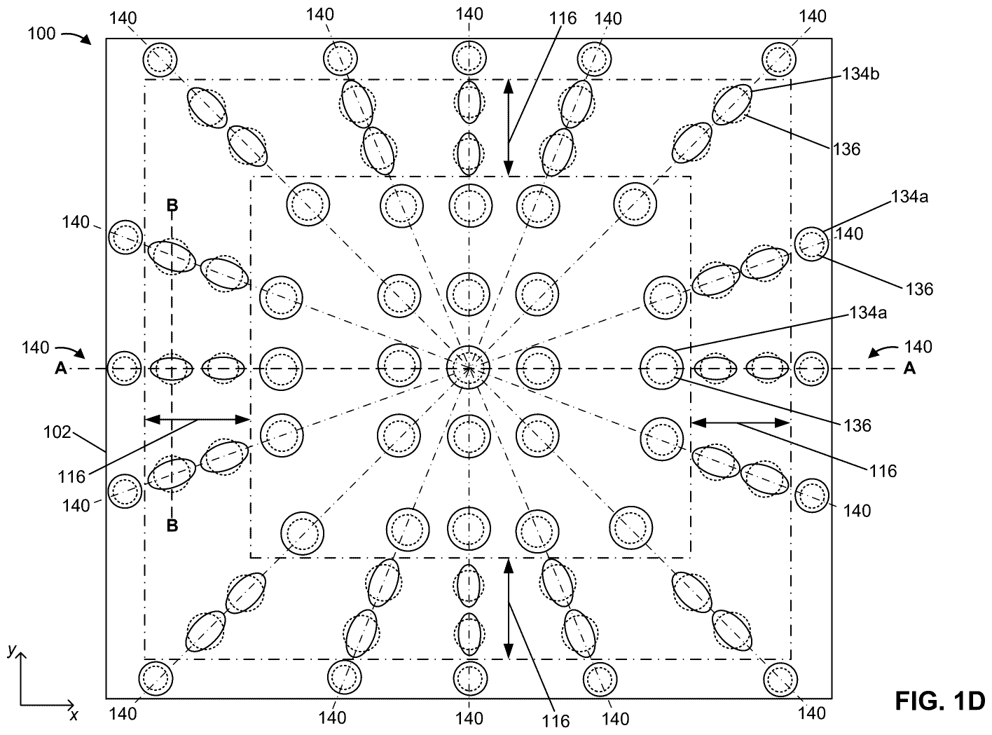

FIGS. 1A-1D are diagrams of an example semiconductor package 100 described herein. FIG. 1A illustrates a cross-section view in an x-direction in the semiconductor package 100. FIG. 1B illustrates a cross-section view in a y-direction in the semiconductor package 100. FIGS. 1C and 1D each illustrate top views of the semiconductor package 100, and illustrate locations of cross-sections A-A and B-B in FIGS. 1A and 1B, respectively.

As shown in FIG. 1A, the semiconductor package 100 includes a packaged semiconductor device that includes a package substrate 102 and one or more semiconductor die packages 104 bonded, attached, mounted, and/or otherwise secured to the package substrate 102. The semiconductor package 100 may be referred to as a 3D package, a 2.5D package, and/or another type of semiconductor package.

As shown in FIG. 1A, a stiffener structure 106 may be included over and/or on the package substrate 102. The semiconductor die package(s) 104 may be positioned within a perimeter of the stiffener structure 106 and may be spaced apart from the stiffener structure 106. The stiffener structure 106 may be included to reduce warpage and bending, and to maintain planarity of the package substrate 102. The stiffener structure 106 may include active circuitry, a non-active structure, or a combination thereof. The stiffener structure 106 may include one or more metal materials, one or more dielectric materials, and/or one or more materials of another type of material.

As further shown in FIG. 1A, a semiconductor die package 104 may include an interposer 108 and one or more integrated circuit (IC) dies (e.g., an IC die 110a, an IC die 110b) bonded, attached, mounted, and/or otherwise secured to the interposer 108. The quantity and arrangement of IC dies illustrated in FIG. 1A is an example, and other quantities and arrangements are within the scope of the present disclosure. In some implementations, a semiconductor die package 104 may include a single IC die.

As shown in FIG. 1A, the one or more IC dies may be horizontally distributed (e.g., in an x-direction and/or in a y-direction) on the interposer 108. In some implementations, one or more of the IC dies 110a and/or 110b are active IC dies that include the active integrated circuits of the semiconductor die package 104 and perform the electrical and processing functions of the semiconductor die package 104. Examples of active IC dies include a logic IC die, a memory IC die, a high-bandwidth memory (HBM) IC die, an input/output (I/O) die, a system-on-chip (SoC) IC die, a dynamic random access memory (DRAM) IC die, a static random access memory (SRAM) IC die, a central processing unit (CPU) IC die, a graphics processing unit (GPU) IC die, a digital signal processing (DSP) IC die, an application specific integrated circuit (ASIC) IC die, and/or another type of active IC die. The active IC dies may be various sizes and/or shapes, and may be positioned in various locations and arrangements on the interposer 108.

In some implementations, one or more of the IC dies 110a and/or 110b are non-active dies. Examples of non-active dies include dummy dies and/or other types of non-active dies. A dummy die may also be referred to as an insertion die, a filler die, and/or another type of die that does not perform electrical and/or processing functions of the semiconductor die package 104. The quantity and/or position of the non-active dies in the top view of the semiconductor die package 104 (e.g., the horizontal arrangement of non-active dies in the top view) may be determined and/or selected to achieve and/or satisfy one or more parameters for semiconductor die package 104. Unused area (e.g., area that is not occupied by at least one IC die) in the horizontal arrangement of IC dies in the semiconductor die package 104 may result in reduced stiffness and/or reduced rigidity for the semiconductor die package 104. This may increase the likelihood of bending, warpage, and/or physical damage to the semiconductor die package 104. Accordingly, the quantity and/or position of the non-active dies may be determined and/or selected to reduce and/or minimize unused area in the horizontal arrangement of the IC dies in the top view. Thus, the non-active dies may be positioned in unused area between two or more active IC dies, may be positioned in unused area adjacent to (or next to) one or more active IC dies, or a combination thereof, to minimize unused area in the horizontal arrangement of IC dies in the top view of the semiconductor die package 104.

The interposer 108 of the semiconductor die package 104 may be attached to the package substrate 102 of the semiconductor package 100 by a plurality of connection structures 112. The connection structures 112 may include a stud, a pillar, a bump, a solder ball, a micro-bump, an under-bump metallization (UBM) structure, and/or another type of connection structure, among other examples. The connection structures 112 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

An underfill material 114 may be included between under the semiconductor die package 104 and between the connection structures 112 of the semiconductor die package 104. The underfill material 114 may include a polymer, one or more fillers dispersed in a resin, an epoxy-based resin, and/or another type of insulating material. The underfill material 114 may extend outward from the semiconductor die package 104 and toward the stiffener structure 106. For example, the underfill material 114 may extend outward in a tapered or sloped manner. As another example, underfill material 114 may extend outward in a concave manner or in a convex manner.

As further shown in FIG. 1A, the semiconductor die package 104 may be spaced apart from the stiffener structure 106. The space between the semiconductor die package 104 and the stiffener structure 106 may define a region 116 around the semiconductor die package 104 between the semiconductor die package 104 and the stiffener structure 106. In some implementations, the underfill material 114 extends into the region 116 between the semiconductor die package 104 and the stiffener structure 106. In some implementations, one or more components such as one or more integrated passive devices (IPDs) may be located on the package substrate 102 within the region 116.

As further shown in FIG. 1A, the package substrate 102 of the semiconductor package 100 may include a substrate core 118 that is sandwiched between a redistribution structure 120a (e.g., a bottom RDL) and a redistribution structure 120b (e.g., a top RDL). Thus, the package substrate 102 may include a vertically arranged (e.g., in the z-direction) stack that includes the redistribution structure 120a, the substrate core 118, and the redistribution structure 120b.

A passivation layer 122a may be included on the bottom of the redistribution structure 120a, and a passivation layer 122b may be included on the top of the redistribution structure 120b. The passivation layers 122a and 122b may each include a solder resist (SR) mask that enables connection structures to be selectively attached to the redistribution structures 120a and 120b. In some implementations, the passivation layers 122a and 122b includes one or more polymer materials, one or more dielectric materials (e.g., a silicon oxide (SiOₓ), a silicon nitride (SiₓN_{y}), a silicon carbide (SiCₓ), a silicon carbon nitride (SiCN), and/or a silicon oxynitride (SiON)), and/or another suitable electrically insulating material.

The substrate core 118 may include substrate layer 124 and one or more interconnect structures 126 extending through the substrate layer 124. The substrate layer 124 may include a silicon (Si) substrate, a dielectric substrate, a polymer substrate, and/or another suitable substrate material. The interconnect structures 126 may include through hole vias (THVs), through integrated fanout vias (TIVs), through silicon vias (TSVs), and/or another type of interconnect structures. The interconnect structures 126 may enable signals and/or power to be distributed between the redistribution structure 120a and the redistribution structure 120b.

As further shown in FIG. 1A, the redistribution structure 120a may include an insulator layer 128a and a plurality of conductive structures included in the insulator layer. The insulator layer 128a may include polyimide, polybenzoxazole (PBO), benzocyclobutene (BCB), an ajinomoto buildup film (ABF), a solder resist (SR) film, a pre-impregnated composite fiber (prepreg), a non-woven glass fabric, and/or another suitable insulator material.

The conductive structures of the redistribution structure 120a may be arranged in a plurality of vertically stacked layers in the z-direction. The layers of conductive structures may extend between a top side of the redistribution structure 120a facing the substrate core 118 and a second side of the redistribution structure 120a facing the bottom of the semiconductor package 100. The layers of conductive structures may include a plurality of alternating layers of metallization layers 130a and interconnect layers 132a. The metallization layers 130a and the interconnect layers 132a are electrically interconnected to provide a signal and/or power path throughout the redistribution structure 120a.

The metallization layers 130a may include a combination of trenches, metallization layers, conductive traces, and/or other types of conductive structures. The interconnect layers 132a may include a combination of vias, interconnects, and/or other types of conductive structures. The metallization layers 130a and the interconnect layers 132a may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

As further shown in FIG. 1A, the redistribution structure 120b may similarly include an insulator layer 128b and a plurality of layers of conductive structures (e.g., metallization layers 130b and interconnect layers 132b) included in the insulator layer 128b. The layers of conductive structures may extend between a top side of the redistribution structure 120b facing the semiconductor die package(s) 104 and a second side of the redistribution structure 120b facing the substrate core 118. The layers of conductive structures may be interconnected to provide a signal and/or power path between the interconnect structures 126 and the semiconductor die package(s) 104.

As further shown in FIG. 1A, at the bottom of the redistribution structure 120a, a layer of bottom conductive pads 134 are included in the insulator layer 128a and electrically coupled to a bottom-most layer of conductive structures (e.g., a bottom-most metallization layer 130a, a bottom-most interconnect layer 132a) of the redistribution structure 120a. The bottom conductive pads 134 may electrically couple the conductive structures of the redistribution structure 120a to package connection pads 136 located in the passivation layer 122a on the bottom of the redistribution structure 120a. In some implementations, the package connection pads 136 include a different electrically conductive material (e.g., aluminum (Al), aluminum copper (AlCu) than the electrically conductive material of the bottom conductive pads (e.g., copper (Cu)) to facilitate adherence of package connection structures 138 to the package connection pads 136. The package connection structures 138 may include solder balls, BGA balls, land grid array (LGA) pads, PGA pins, and/or another type of connection structures that enable the semiconductor package 100 to be attached (e.g., soldered, bonded, socketed) to another device or layer.

As shown in FIG. 1A, a subset of the bottom conductive pads 134 (e.g., bottom conductive pads 134a) may be located outside of the region 116 that is laterally between the semiconductor die package 104 and the stiffener structure 106. For example, bottom conductive pads 134a may be located under the semiconductor die package 104 and under the stiffener structure 106. Another subset of the bottom conductive pads 134 (e.g., bottom conductive pads 134b) may be located within the region 116 that is laterally between the semiconductor die package 104 and the stiffener structure 106. The package substrate 102 in the region 116 that is laterally between the semiconductor die package 104 and the stiffener structure 106 may be susceptible to bending due to stresses in the package substrate 102 caused by mismatches in the rates of thermal expansion and contraction between the insulator layers 128a and 128b and the conductive structures in the redistribution structures 120a and 120b. Accordingly, the bottom conductive pads 134b located within the region 116 may have a physically larger size compared to the size of the bottom conductive pads 134a outside of the region 116 and compared to the size of the package connection pads 136 to resist bending of the package substrate 102 in the region 116, thereby reducing the likelihood of cracking and/or delamination in the package substrate 102.

The package connection pads 136 may have a lateral width (or diameter) in the x-direction indicated in FIG. 1A as a dimension D1. The bottom conductive pads 134a outside of the region 116 may have a lateral width (or diameter) in the x-direction indicated in FIG. 1A as a dimension D2. The bottom conductive pads 134b within the region 116 may have a lateral width (or diameter) in the x-direction indicated in FIG. 1A as a dimension D3. The lateral width (or diameter) of the bottom conductive pads 134b in the x-direction is greater than the lateral width (or diameter) of the bottom conductive pads 134a in the x-direction (e.g., D3>D2 in the x-direction), and the lateral width (or diameter) of the bottom conductive pads 134b in the x-direction is greater than the lateral width (or diameter) of the package connection pads 136 in the x-direction (e.g., D3>D1 in the x-direction). The bottom conductive pads 134b may extend laterally outward past the ends of the package connection pads 136 vertically adjacent (e.g., in the z-direction) to the bottom conductive pads 134b, whereas the package connection pads 136 vertically adjacent to the bottom conductive pads 134a may extend laterally outward past (or may be laterally in line with) the ends of the bottom conductive pads 134a.

In some implementations, the lateral width (or diameter) (dimension D3) of the bottom conductive pads 134b in the x-direction is included in a range of approximately 500 microns to approximately 800 microns, whereas the lateral width (or diameter) (dimension D1) of the package connection pads 136 in the x-direction may be included in a range of approximately 450 microns to approximately 700 microns. If the lateral width (or diameter) of the bottom conductive pads 134b in the x-direction is less than approximately 500 microns, the bottom conductive pads 134b may not provide sufficient stiffness at the bottom of the redistribution structure 120a to adequately resist bending of the package substrate 102. If the lateral width (or diameter) of the bottom conductive pads 134b in the x-direction is greater than approximately 800 microns, the size of the bottom conductive pads 134b may restrict the layout of conductive structures and package connection structures 138 in the redistribution structure 120a. However, other values and ranges other than approximately 500 microns to approximately 800 microns for the lateral width (or diameter) of the bottom conductive pads 134b in the x-direction are within the scope of the present disclosure. Moreover, other values and ranges other than approximately 450 microns to approximately 700 microns for the lateral width (or diameter) of the package connection pads 136 in the x-direction are within the scope of the present disclosure.

As shown in the cross-section view in FIG. 1B, the lateral width (or diameter) (dimension D4) of the bottom conductive pads 134b (e.g., the bottom conductive pads 134 located in the region 116) in the y-direction may be less than the lateral width (or diameter) (dimension D1) of the package connection pads 136 in the y-direction. Thus, in the y-direction, a bottom conductive pad 134b may be located within a footprint of a package connection pad 136 that is vertically adjacent to the bottom conductive pad 134b.

In some implementations, the lateral width (or diameter) (dimension D4) of the bottom conductive pads 134b (e.g., the bottom conductive pads 134 located in the region 116) in the y-direction may be included in a range of approximately 400 microns to approximately 650 microns, whereas the lateral width (or diameter) (dimension D1) of the package connection pads 136 in the y-direction may be included in a range of approximately 450 microns to approximately 700 microns. If the lateral width (or diameter) of the bottom conductive pads 134b in the y-direction is less than approximately 400 microns, the bottom conductive pads 134b may not provide sufficient stiffness at the bottom of the redistribution structure 120a to adequately resist bending of the package substrate 102. If the lateral width (or diameter) of the bottom conductive pads 134b in the y-direction is greater than approximately 650 microns, the size of the bottom conductive pads 134b may restrict the layout of conductive structures and package connection structures 138 in the redistribution structure 120a. However, other values and ranges other than approximately 400 microns to approximately 650 microns for the lateral width (or diameter) of the bottom conductive pads 134b in the y-direction are within the scope of the present disclosure.

As shown in the top view in FIG. 1C, the stiffener structure 106 may be located along the outer edges of the package substrate 102. Accordingly, the package substrate 102 may be outlined or surrounded by a stiffener structure 106. The semiconductor die package 104 may be located within a perimeter of the stiffener structure 106 such that the stiffener structure 106 surrounds the semiconductor die package 104.

As further shown in FIG. 1C, the bottom conductive pads 134b located within the region 116 laterally between the semiconductor die package 104 and the stiffener structure 106 may be elongated in a direction along radial axes 140 through the approximate center of the semiconductor package 100 and through an approximate center of the bottom conductive pads 134b. For example, along the location of the cross-section A-A illustrated in FIG. 1C, the bottom conductive pads 134b located within the region 116 laterally between the semiconductor die package 104 and the stiffener structure 106 may be elongated in the x-direction direction along a radial axis 140 through the approximate center of the semiconductor package 100 and through an approximate center of the bottom conductive pads 134b. Other bottom conductive pads 134b located within the region 116 laterally between the semiconductor die package 104 and the stiffener structure 106 may be elongated along similar radial axes 140 through the approximate center of the semiconductor package 100 and through approximate centers of the other bottom conductive pads 134b. Thus, the bottom conductive pads 134b are oriented radially around the package substrate 102 such that the elongated top view shapes of the bottom conductive pads 134b point toward the center of the semiconductor package 100. Orienting the bottom conductive pads 134b such that the elongated top view shapes of the bottom conductive pads 134b point toward the center of the semiconductor package 100 enables the package substrate 102 to further resist bending along the radial axes 140, in that the greater width (e.g., the dimension D3) of the bottom conductive pads 134b along the radial axes 140 provides increased stiffness in the direction of the radial axes 140.

As shown in a close-up view of a bottom conductive pad 134b and an underlying package connection pad 136, the bottom conductive pad 134b and the package connection pad 136 may have different top view shapes. The package connection pad 136 may have an approximate circle top view shape (or another top view shape), and the bottom conductive pad 134b may have an approximate oval top view shape, an approximate elliptical top view shape, an approximate obround top view shape, and/or another (standard or non-standard) oblong or elongated top view shape. The bottom conductive pad 134b may have a major axis 142, that is aligned with the radial axis 140 through the approximate center of the semiconductor package 100 and the approximate center of the bottom conductive pad 134b, and a minor axis 144 that is approximately perpendicular to the major axis 142 (and thus, approximately perpendicular to the radial axis 140).

The width of the bottom conductive pad 134b along the major axis 142 (e.g., the dimension D3) is greater than the width of the bottom conductive pad 134b along the minor axis 144 (e.g., the dimension D4). The bottom conductive pad 134b may have an overlap region 146 that overlaps with the underlying package connection pad 136. However, the width of the bottom conductive pad 134b along the major axis 142 (e.g., the dimension D3) is greater than the width of the package connection pad 136 (e.g., the dimension D1) along the radial axis 140, resulting in opposing overhang regions 148 where the bottom conductive pad 134b extends laterally outward past the edges of the package connection pad 136. Conversely, the width of the bottom conductive pad 134b along the minor axis 144 (e.g., the dimension D4) is less than the width of the package connection pad 136 (e.g., the dimension D1), resulting in overhang regions 150 where the package connection pad 136 extends laterally outward past the edges of the bottom conductive pad 134b.

FIG. 1D illustrates a top view of the semiconductor package 100 with the semiconductor die package 104 and the stiffener structure 106 omitted to illustrate the details of the bottom conductive pads 134a and the associated package connection pads 136 under the semiconductor die package 104 and under the stiffener structure 106. As shown in FIG. 1D, the bottom conductive pads 134a outside of the region 116 and the bottom conductive pads 134b may have different top view shapes. For example, the bottom conductive pads 134a may each have an approximate circle top view shape (or another top view shape), and the bottom conductive pads 134b may each have an approximate oval top view shape, an approximate elliptical top view shape, an approximate obround top view shape, and/or another (standard or non-standard) oblong or elongated top view shape. The bottom conductive pads 134a outside of the region 116 may have approximately a same top view shape as the package connection pads 136.

As indicated above, FIGS. 1A-1D are provided as an example. Other examples may differ from what is described with regard to FIGS. 1A-1D.

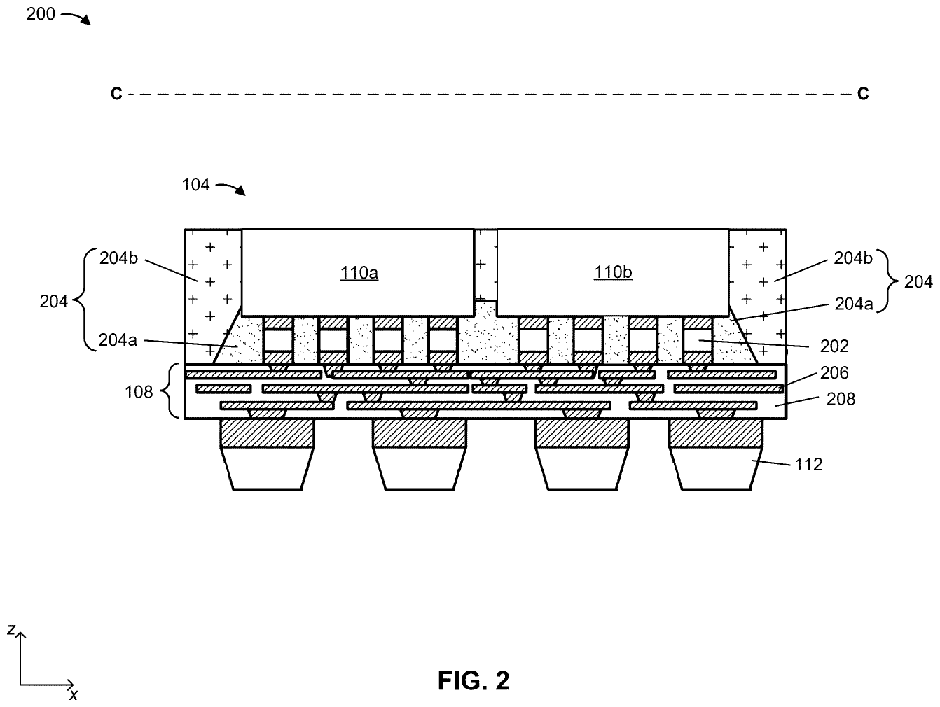

FIG. 2 is a diagram of an example 200 of a semiconductor die package 104 described herein. FIG. 2 illustrates a cross-section view of the semiconductor die package 104 along the line C-C in FIG. 1C in the x-direction. As shown in FIG. 2, the IC dies (e.g., the IC dies 110a and/or 110b) may be attached to, mounted to, and/or bonded to the interposer 108 of the semiconductor die package 104.

The IC dies 110a and/or 110b may be attached to the interposer 108 by a plurality of connection structures 202. The connection structures 202 may include a stud, a pillar, a bump, a solder ball, a micro-bump, a UBM structure, and/or another type of connection structure, among other examples. The connection structures 202 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 202 may connect lands (e.g., pads) on bottom surfaces of the IC dies 110a and/or 110b to lands on a top surface of the interposer 108. In some implementations, the connection structures 202 may include one or more electrical connections for signaling (e.g., corresponding lands of the IC dies and/or the interposer 108 are electrically connected to respective circuitry and/or traces of the IC dies and/or the interposer 108). In some implementations, the connection structures 202 may include one or more mechanical connections for attachment purposes and/or spacing purposes (e.g., corresponding lands of the IC dies and/or the interposer 108 are not electrically connected to respective circuitry and/or traces of the IC dies and/or the interposer 108). In some implementations, one or more of the connection structures 202 may function both electrically and mechanically.

As further shown in FIG. 2, one or more types of filler materials 204 may be included above the interposer 108 and in areas surrounding the IC dies and/or the connection structures 202. For example, an underfill material 204a may be included between the connection structures 202 under the IC dies 110a and/or 110b. As another example, an encapsulant material (also referred to as a molding compound) 204b may be included over and/or on the interposer 108 and/or over and/or on portions of the underfill material 204a around the perimeter of the semiconductor die package 104.

The underfill material 204a may include a polymer, one or more fillers dispersed in a resin, an epoxy-based resin, and/or another type of insulating material. In some implementations, the underfill material 204a fills in the gaps between the IC dies 110a and/or 110b. In some implementations, the underfill material 204a may fully fill the gaps approximately up to a top surface of the IC dies 110a and/or 110b. The underfill material 204a may extend outward from one or more of the IC dies 110a and/or 110b toward the perimeter of the semiconductor die package 104. For example, the underfill material 204a may extend outward in a tapered or sloped manner. As another example, the underfill material 204a may extend outward in a concave manner or in a convex manner.

The encapsulant material 204b may include a polymer, one or more fillers dispersed in a resin, an epoxy-based resin, and/or another type of insulating material. In some implementations, the encapsulant material 204b may fully surround the top surfaces of the IC dies 110a and/or 110b such that the encapsulant material 204b protects the IC dies 110a and/or 110b in the semiconductor die package 104.

In some implementations, the interposer 108 includes a redistribution structure (e.g., an RDL). In these implementations, the interposer 108 includes a plurality of conductive traces 206 (e.g., copper (Cu) traces) in a base layer 208 formed of a polymer material, a molding material, and/or a dielectric material (e.g., silicon oxide (SiOₓ such as SiO₂), undoped silicate glass (USG)). In some implementations, the interposer 108 includes a silicon interposer. In these implementations, the interposer 108 includes a plurality of conductive traces 206 (e.g., copper (Cu) traces) in a base layer 208 that is formed of silicon (Si).

The interposer 108 may be configured to distribute electrical signals between the connection structures 202 and connection structures 112 on opposing sides of the interposer 108. The conductive traces 206 and the connection structures 112 may include one or more materials such as a gold (Au) material, a copper (Cu) material, a silver (Ag) material, a nickel (Ni) material, a tin (Sn) material, or a palladium (Pd) material, among other examples. In some implementations, the conductive traces 206 include one or more conductive vertical access connection structures (vias) that connect one or more metallization layers of the conductive traces 206.

As indicated above, FIG. 2 is provided as an example. Other examples may differ from what is described with regard to FIG. 2.

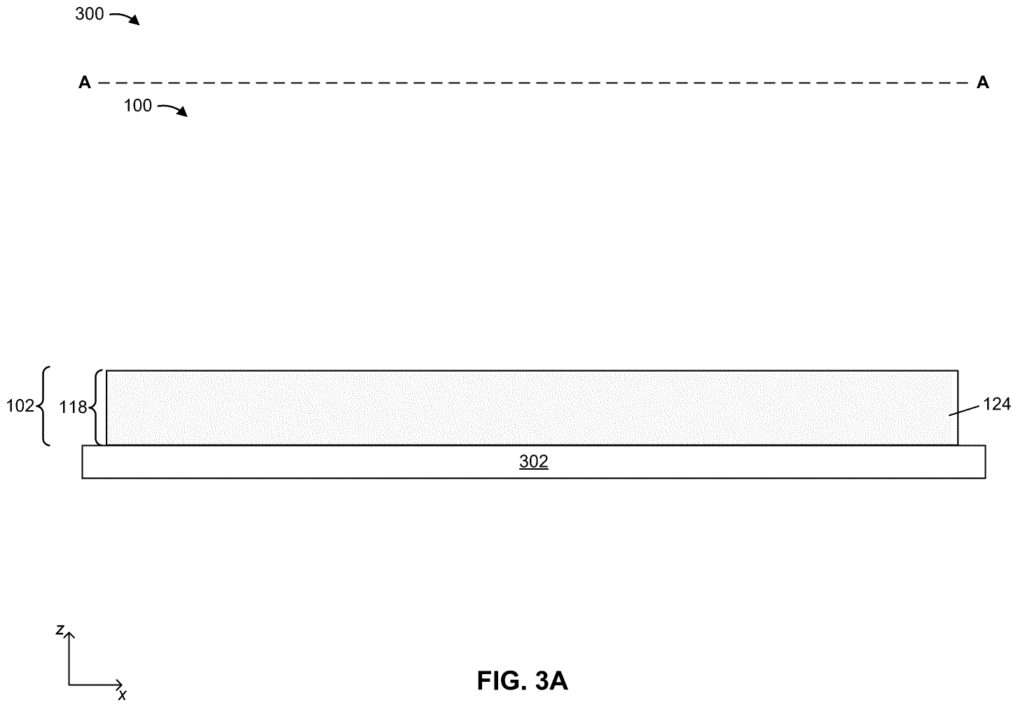

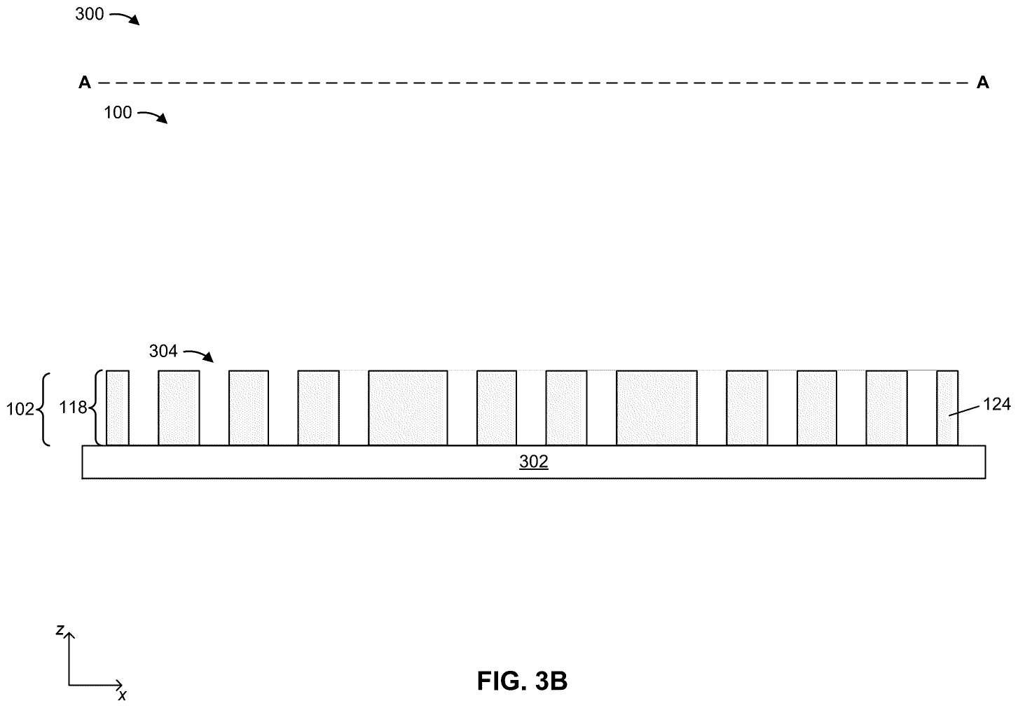

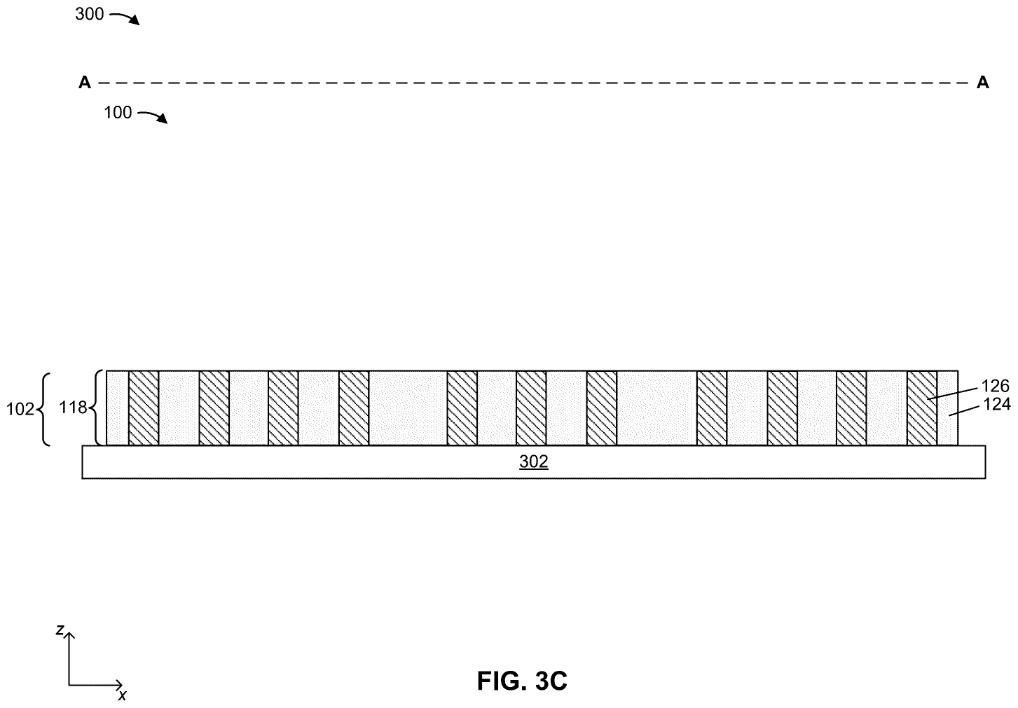

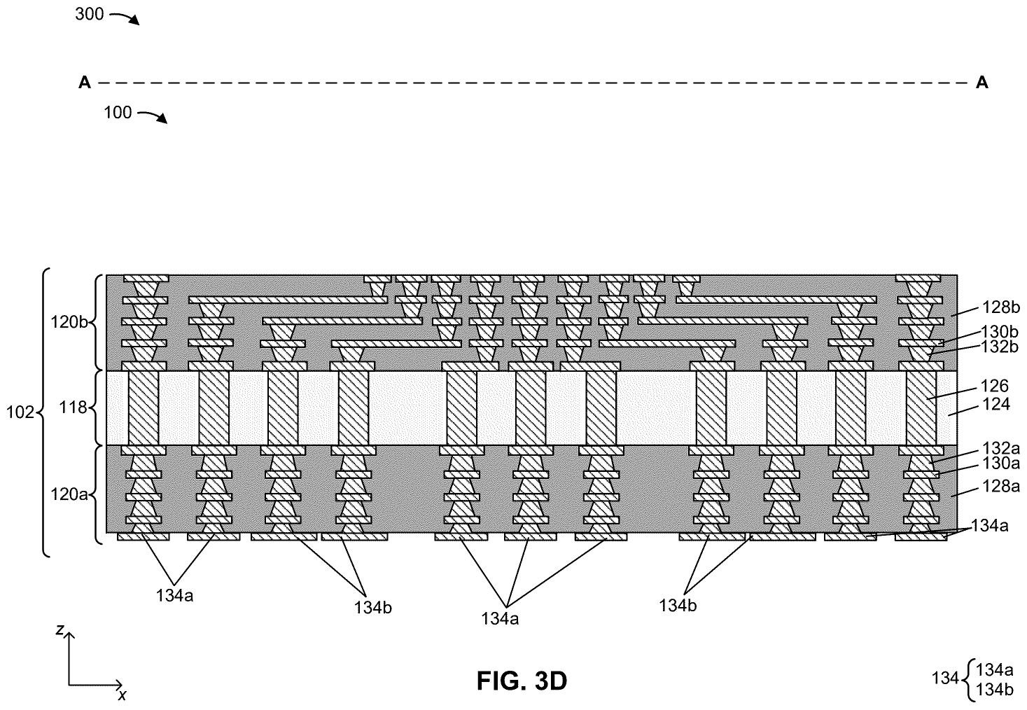

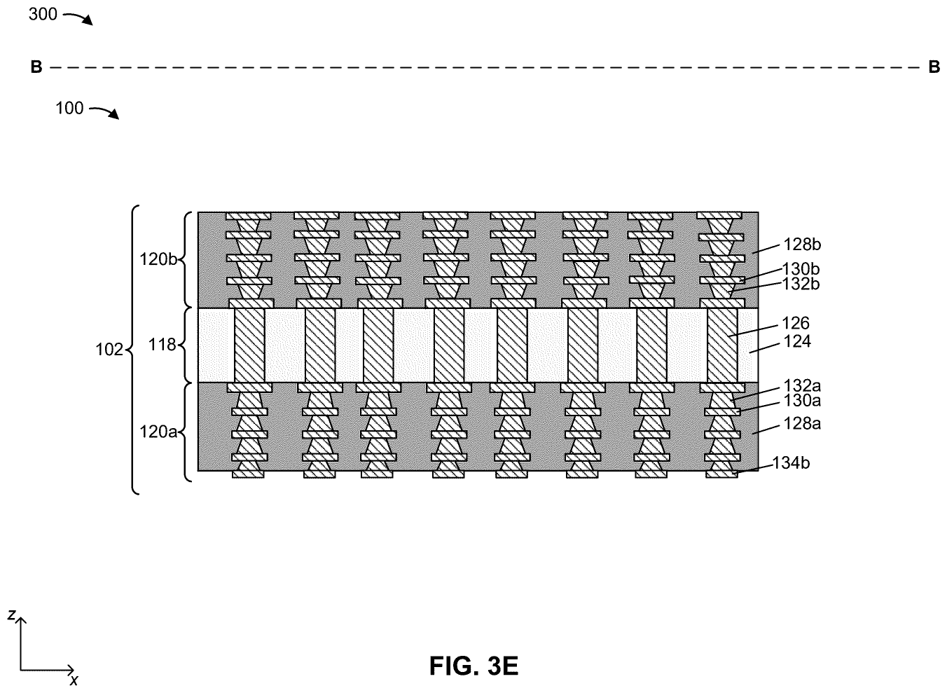

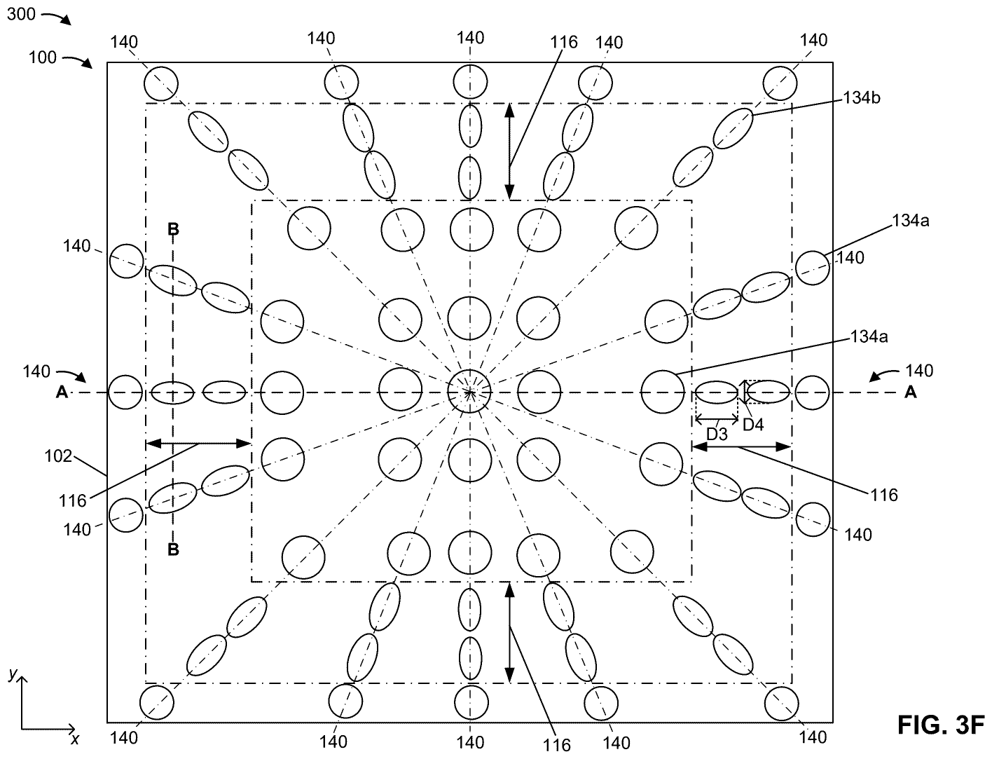

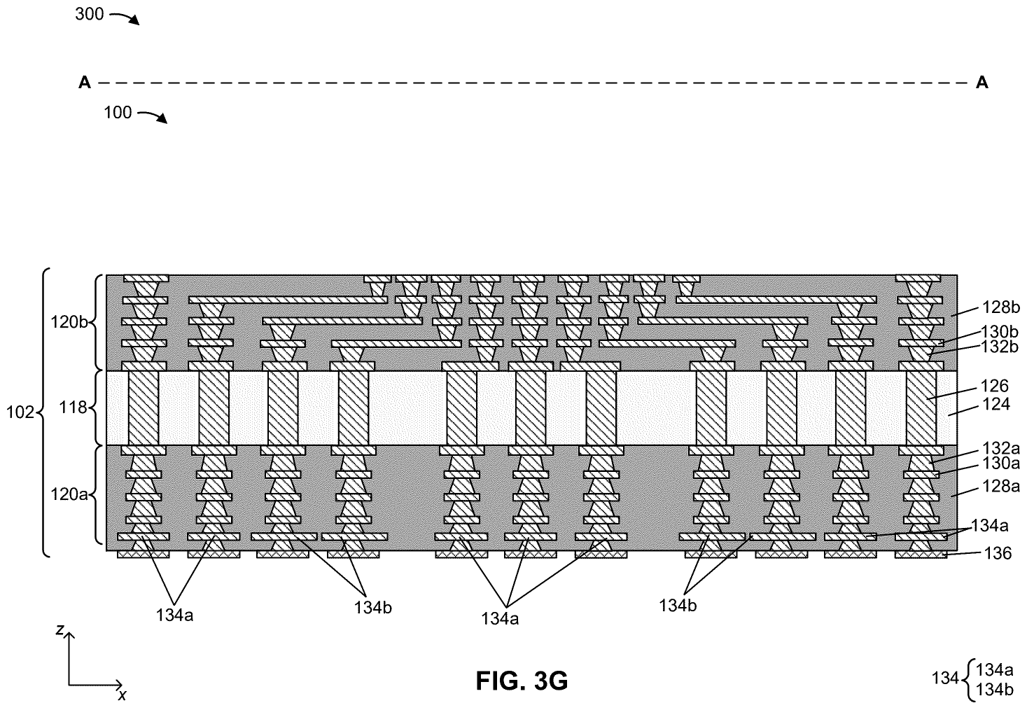

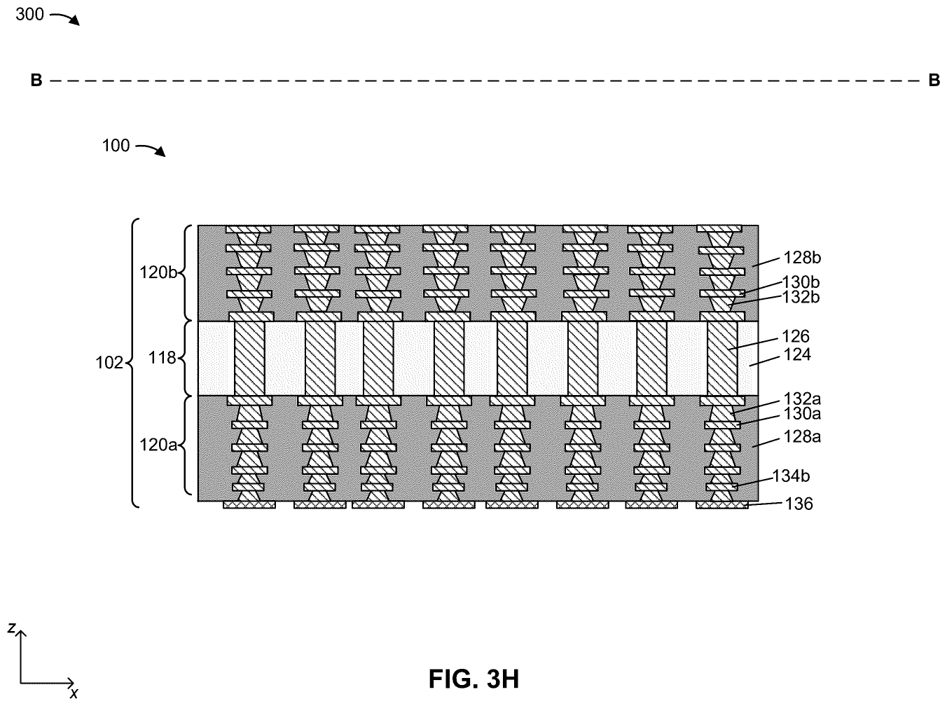

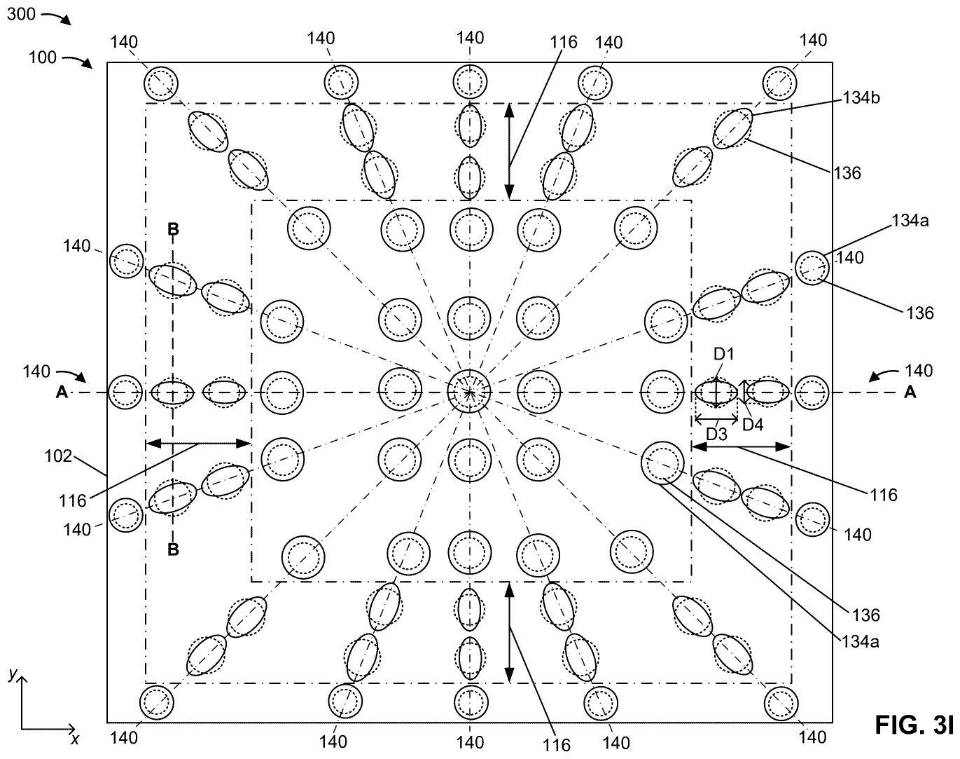

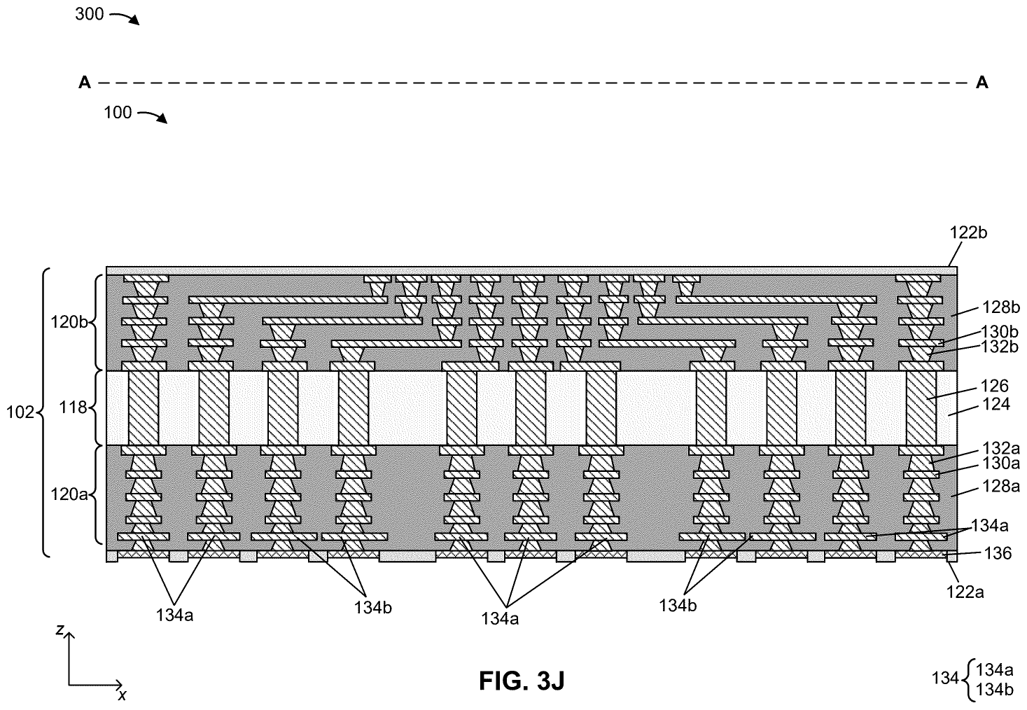

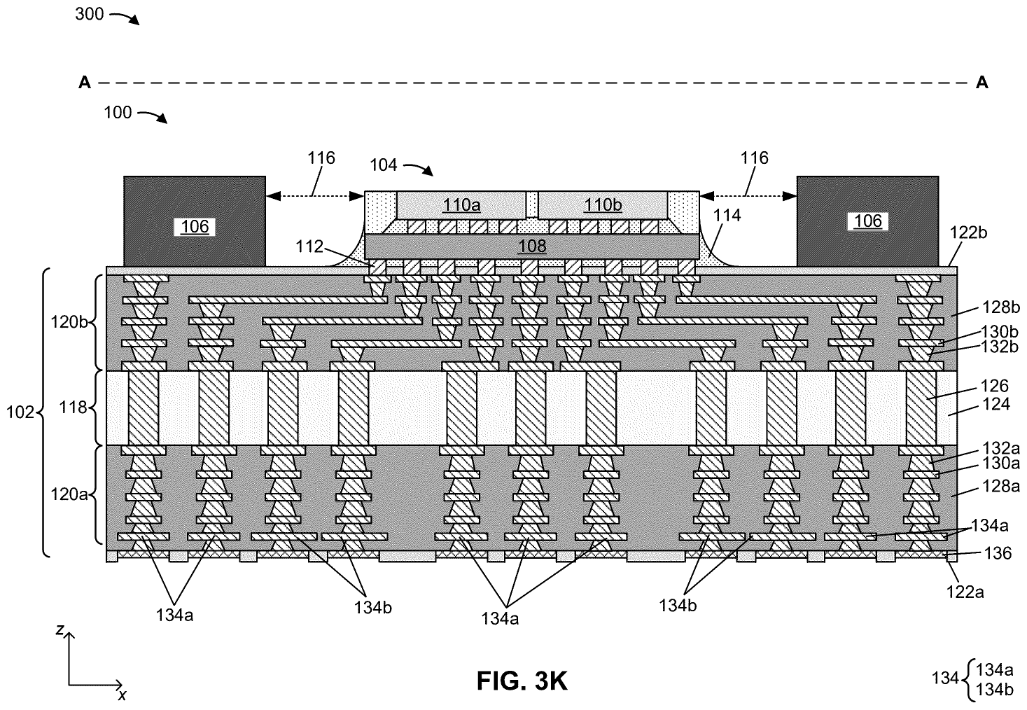

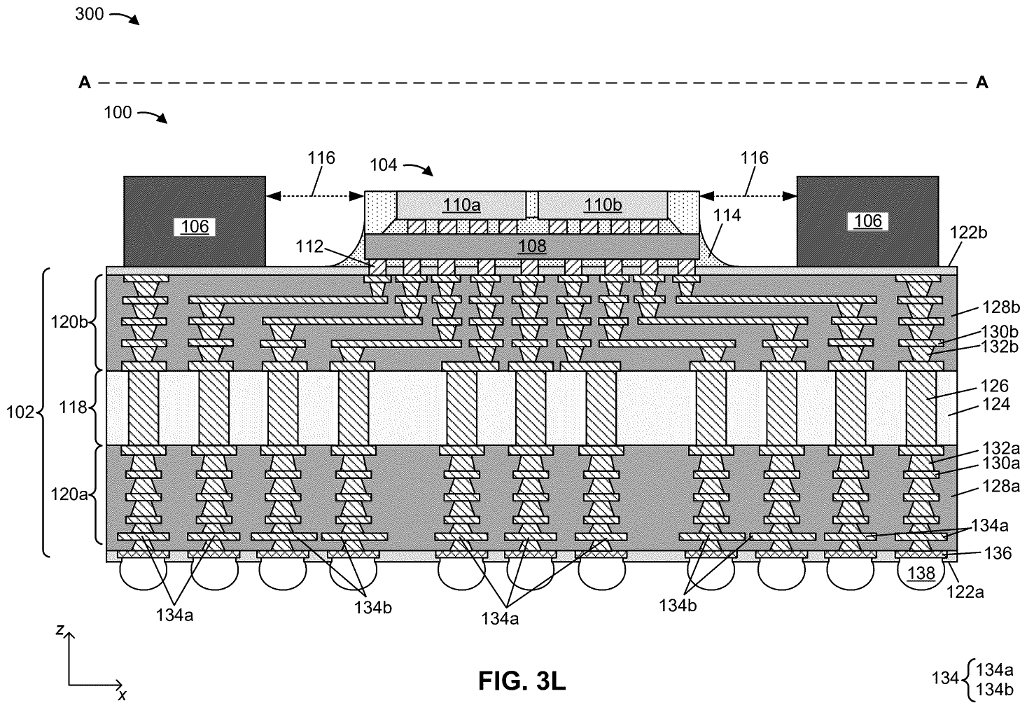

FIGS. 3A-3L are diagrams of an example implementation 300 of forming the semiconductor package 100 described herein. One or more of semiconductor processing tools may be used to perform one or more of the operations described in connection with FIGS. 3A-3L, such as a deposition tool, an exposure tool (e.g., a photolithography tool), a developer tool, an etch tool, a planarization tool (e.g., a chemical-mechanical planarization (CMP) tool, a wafer grinding tool), a pick-and-place tool, a soldering tool, and/or another semiconductor processing tool.

Turning to FIG. 3A, the substrate layer 124 of the substrate core 118 of the package substrate 102 of the semiconductor package 100 may be provided. The substrate layer 124 may be provided on a carrier substrate 302 to facilitate processing of the substrate layer 124.

For example, and as shown in FIG. 3B, the substrate layer 124 may be provided on a carrier substrate 302 to facilitate forming recesses 304 fully through the substrate layer 124. In some implementations, a pattern in a photoresist layer is used to etch the substrate layer 124 to form the recesses 304. In these implementations, a deposition tool may be used to form the photoresist layer on the substrate layer 124 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate layer 124 based on the pattern to form the recesses 304. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 124 based on a pattern.

As shown in FIG. 3C, interconnect structures 126 may be formed in the recesses 304 such that the interconnect structures 126 extend through the substrate layer 124 of the substrate core 118. A deposition tool may be used to deposit the interconnect structures 126 using a chemical vapor deposition (CVD) technique, a physical vapor deposition (PVD) technique, an atomic layer deposition (ALD) technique, an electroplating technique, and/or another suitable deposition technique. The interconnect structures 126 may be deposited in one or more deposition operations. In some implementations, a seed layer is first deposited, and the interconnect structures 126 is deposited on the seed layer. In some implementations, a liner is first deposited in the recesses 304, and the interconnect structures 126 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the interconnect structures 126 after the interconnect structures 126 are deposited.

As shown in FIGS. 3D and 3E, the redistribution structure 120a of the package substrate 102 may be formed over a first side of the substrate layer 124 of the substrate core 118, and the redistribution structure 120b of the package substrate 102 may be formed over a second side of the substrate layer 124 of the substrate core 118 vertically opposite (e.g., in the z-direction) the redistribution structure 120a. In some implementations, the redistribution structure 120a is formed first, followed by formation of the redistribution structure 120b. In some implementations, the redistribution structure 120b is formed first, followed by formation of the redistribution structure 120a. In some implementations, the redistribution structures 120a and 120b are formed together in the same processes.

Forming the redistribution structure 120a may include forming the insulator layer 128a of the redistribution structure 120a over the first side of the substrate core 118, and forming conductive structures (e.g., metallization layers 130a, interconnect layers 132a) of the redistribution structure 120a in the insulator layer 128a. Similarly, forming the redistribution structure 120b may include forming the insulator layer 128b of the redistribution structure 120b over the second side of the substrate core 118, and forming conductive structures (e.g., metallization layers 130b, interconnect layers 132b) of the redistribution structure 120b in the insulator layer 128b.

In some implementations, the insulator layer 128a and the conductive structures of the redistribution structure 120a may be formed as a plurality of layers that are stacked in the z-direction over the first side of the substrate layer 124. For example, a first portion of the insulator layer 128a may be formed, recesses may be formed in the first portion of the insulator layer 128a, and a first metallization layer 130a may be formed in the first portion of the insulator layer 128a such that the first metallization layer 130a is coupled to the interconnect structures 126. A second portion of the insulator layer 128a may be formed on the first portion, recesses may be formed in the second portion of the insulator layer 128a, and a first interconnect layer 132a may be formed in the second portion of the insulator layer 128a such that the first interconnect layer 132a is coupled to the first metallization layer 130a. Additional metallization layers 130a and/or additional interconnect layers 132a may be formed in a similar manner.

A deposition tool may be used to deposit the insulator layer 128a using a CVD technique, a PVD technique, an ALD technique, and/or another suitable deposition technique. Additionally and/or alternatively, material of the insulator layer 128a may be dispensed onto the first side of the substrate layer 124 and cured.

A deposition tool may be used to deposit the metallization layers 130a and/or the interconnect layers 132a using a CVD technique, a PVD technique, an ALD technique, an electroplating technique, and/or another suitable deposition technique. The metallization layers 130a and/or the interconnect layers 132a may be deposited in one or more deposition operations. In some implementations, a seed layer is first deposited, and the metallization layers 130a and/or the interconnect layers 132a are deposited on the seed layer. In some implementations, a liner is first deposited in the recesses, and the metallization layers 130a and/or the interconnect layers 132a are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the metallization layers 130a and/or the interconnect layers 132a after the metallization layers 130a and/or the interconnect layers 132a are deposited.

In some implementations, the insulator layer 128b and the conductive structures (e.g., the metallization layers 130b and/or the interconnect layers 132b) of the redistribution structure 120b may be formed in a similar manner as described for the insulator layer 128a and the conductive structures (e.g., the metallization layers 130a and/or the interconnect layers 132a) of the redistribution structure 120a.

As further shown in FIGS. 3D and 3E, an additional portion of the insulator layer 128a of the redistribution structure 120a may be formed over the conductive structures of the redistribution structure 120a. As further shown in FIGS. 3D, 3E, and 3F, a layer of bottom conductive pads 134 of the redistribution structure 120a may be formed in the additional portion of the insulator layer 128a. A deposition tool may be used to deposit the layer of bottom conductive pads 134 using a CVD technique, a PVD technique, an ALD technique, an electroplating technique, and/or another suitable deposition technique. The layer of bottom conductive pads 134 may be deposited in one or more deposition operations. In some implementations, a seed layer is first deposited, and the layer of bottom conductive pads 134 are deposited on the seed layer. In some implementations, a liner is first deposited in the recesses, and the layer of bottom conductive pads 134 are deposited on the liner. The liner may include a barrier liner, an adhesion liner, and/or another type of liner. Examples of liner materials may include tantalum nitride (TaN), titanium nitride (TiN), and/or another suitable liner material. In some implementations, a planarization tool is used to perform a planarization operation (e.g., a CMP operation) to planarize the bottom conductive pads 134.

As shown in FIGS. 3D-3F, bottom conductive pads 134a may be formed outside of a region 116 that is to be located laterally between a semiconductor die package 104 and a stiffener structure 106 (the semiconductor die package 104 and the stiffener structure 106 are to be subsequently placed on the package substrate 102). As shown in FIGS. 3D-3F, bottom conductive pads 134b may be formed within the region 116 that are to be located laterally between a semiconductor die package 104 and a stiffener structure 106 that are to be subsequently placed on the package substrate 102.

As shown in FIG. 3F, the bottom conductive pads 134b may have lateral widths (dimension D3) along radial axes 140 through the approximate center of the semiconductor package 100 and through an approximate center of the bottom conductive pads 134b that are greater than lateral widths (dimension D4) of the bottom conductive pads 134b in directions approximately perpendicular to the radial axes 140. Accordingly, the bottom conductive pads 134b are formed such that the bottom conductive pads 134b are elongated along radial axes 140 through the approximate center of the semiconductor package 100 and through an approximate center of the bottom conductive pads 134b. For example, along the location of the cross-section A-A illustrated in FIG. 3F, the bottom conductive pads 134b are formed such that the bottom conductive pads 134b are elongated in the x-direction along a radial axis 140 through the approximate center of the semiconductor package 100 and through an approximate center of the bottom conductive pads 134b. Other bottom conductive pads 134b may be formed to be elongated along similar radial axes 140 through the approximate center of the semiconductor package 100 and through approximate centers of the other bottom conductive pads 134b. Thus, the bottom conductive pads 134b are oriented radially around the package substrate 102 such that the elongated top view shapes of the bottom conductive pads 134b point toward the center of the semiconductor package 100.

As shown in FIGS. 3G, 3H, package connection pads 136 may be formed such that the connection pad pads 136 are electrically coupled and/or physically coupled to the layer of bottom conductive pads 134 of the redistribution structure 120a. A deposition tool may be used to deposit the package connection pads 136 using a CVD technique, a PVD technique, an ALD technique, and/or another suitable deposition technique.

As shown in FIG. 3I, the bottom conductive pads 134 and the package connection pads 136 may be vertically adjacent (e.g., in the z-direction) in the package substrate 102 such that the bottom conductive pads 134 and the package connection pads 136 at least partially overlap in the z-direction. The package connection pads 136 may be formed to have a lateral width (or diameter) (dimension D1) that is less than the lateral width (or diameter) of the bottom conductive pads 134b (dimension D3) along the radial axes 140. Thus, the bottom conductive pads 134b may extend laterally outward past the ends of the package connection pads 136 vertically adjacent (e.g., in the z-direction) to the bottom conductive pads 134b along the radial axes 140, whereas the package connection pads 136 vertically adjacent to the bottom conductive pads 134a may extend laterally outward past (or may be laterally in line with) the ends of the bottom conductive pads 134a. The package connection pads 136 may also be formed such that the lateral width (or diameter) (dimension D1) of the package connection pads 136 is greater than the lateral width (or diameter) (dimension D4) of the bottom conductive pads 134b in directions approximately perpendicular to the radial axes 140.

As shown in FIG. 3J, a passivation layer 122a may be formed over the redistribution structure 120a, and a passivation layer 122b may be formed over the redistribution structure 120b. A deposition tool may be used to deposit the passivation layers 122a and 122b using a CVD technique, a PVD technique, an ALD technique, and/or another suitable deposition technique. In some implementations, a planarization tool may be used to perform a planarization operation (e.g., a CMP operation) to planarize the passivation layers 122a and 122b.

In some implementations, the package connection pads 136 are formed first, and the passivation layer 122a is formed around the package connection pads 136. In some implementations, the passivation layer 122a is formed first, and the package connection pads 136 are formed in the passivation layer 122a. In these implementations, openings through the passivation layer 122a may be formed by forming sacrificial structures, forming the passivation layer 122a around the sacrificial structures, subsequently removing the sacrificial structures, and forming the package connection pads 136 in the openings in the passivation layer 122a left behind by the sacrificial structures.

As shown in FIG. 3K, a pick-and-place tool may be used to place one or more semiconductor die packages 104 on the package substrate 102 of the semiconductor package 100. For example, the one or more semiconductor die packages 104 may be placed on a metallization layer 130b of the redistribution structure 120b, and a solder tool may be used to perform a solder operation (e.g., wave solder operation, a reflow solder operation) to attach the one or more semiconductor die packages 104 to the package substrate 102. As another example, a bonding tool may be used to perform a bonding operation to bond the connection structures 112 of the one or more semiconductor die packages 104 to a metallization layer 130b of the redistribution structure 120b.

As further shown in FIG. 3K, the stiffener structure 106 may be placed on the package substrate 102. The stiffener structure 106 may be attached to the redistribution structure 120b using an epoxy, an adhesive, and/or may otherwise be secured to the redistribution structure 120b.

As shown in FIG. 3L, package connection structures 138 may be attached to the package connection pads 136 at the bottom of the package substrate 102 of the semiconductor package 100. For example, solder balls or UBM structures may be attached to the package connection pads 136 at the bottom of the redistribution structure 120a. The package connection structures 138 may be attached to the bottom of the package substrate 102 using the passivation layer 122a as a solder mask.

As indicated above, FIGS. 3A-3L are provided as an example. Other examples may differ from what is described with regard to FIGS. 3A-3L.

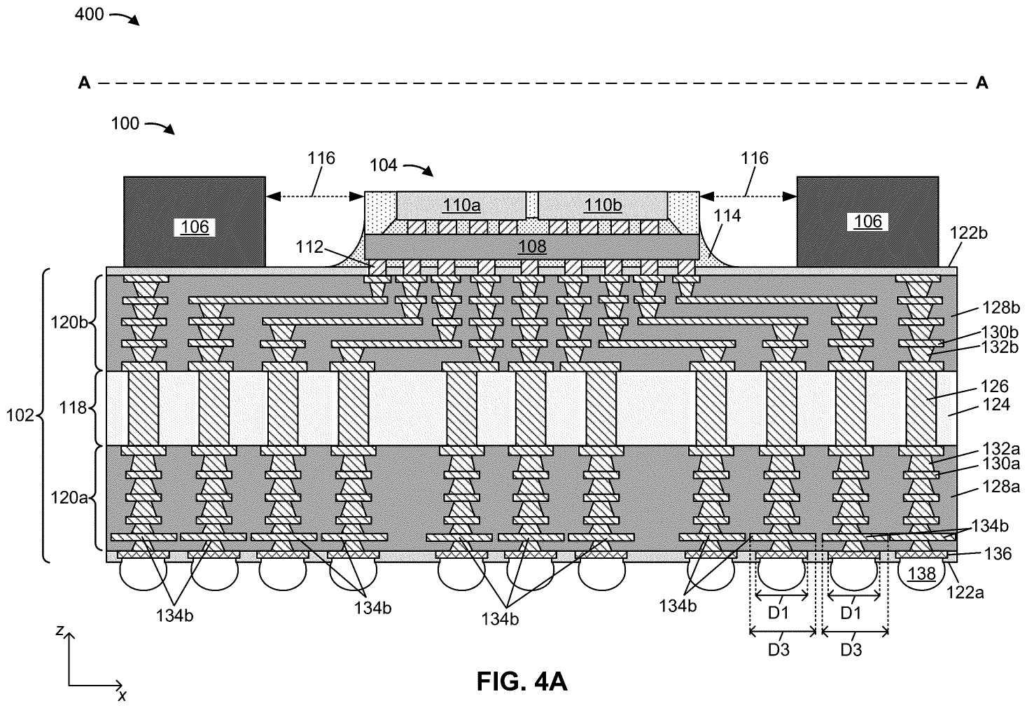

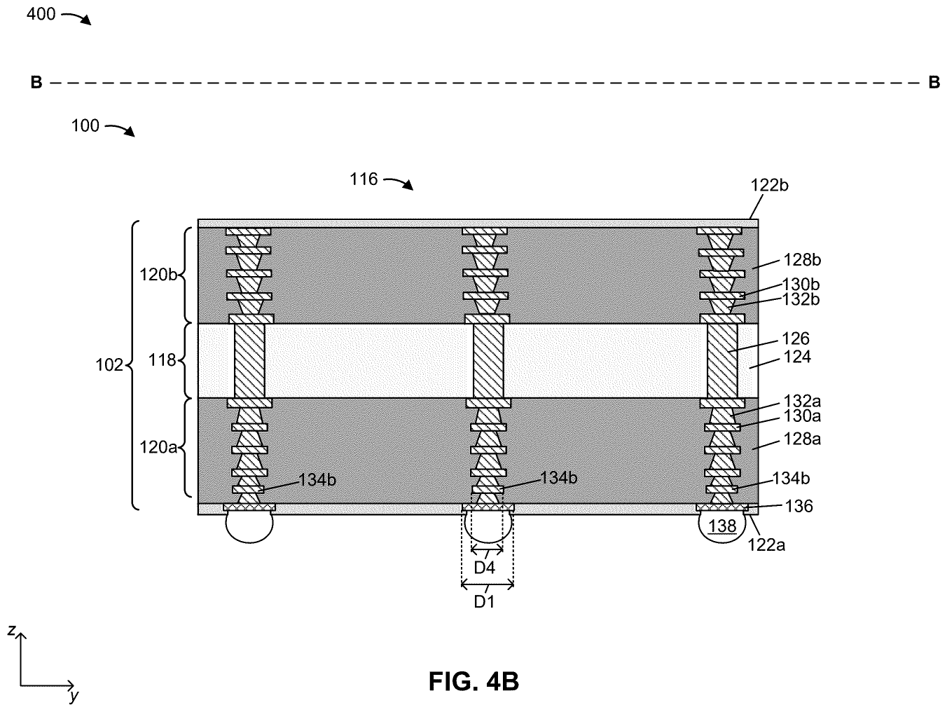

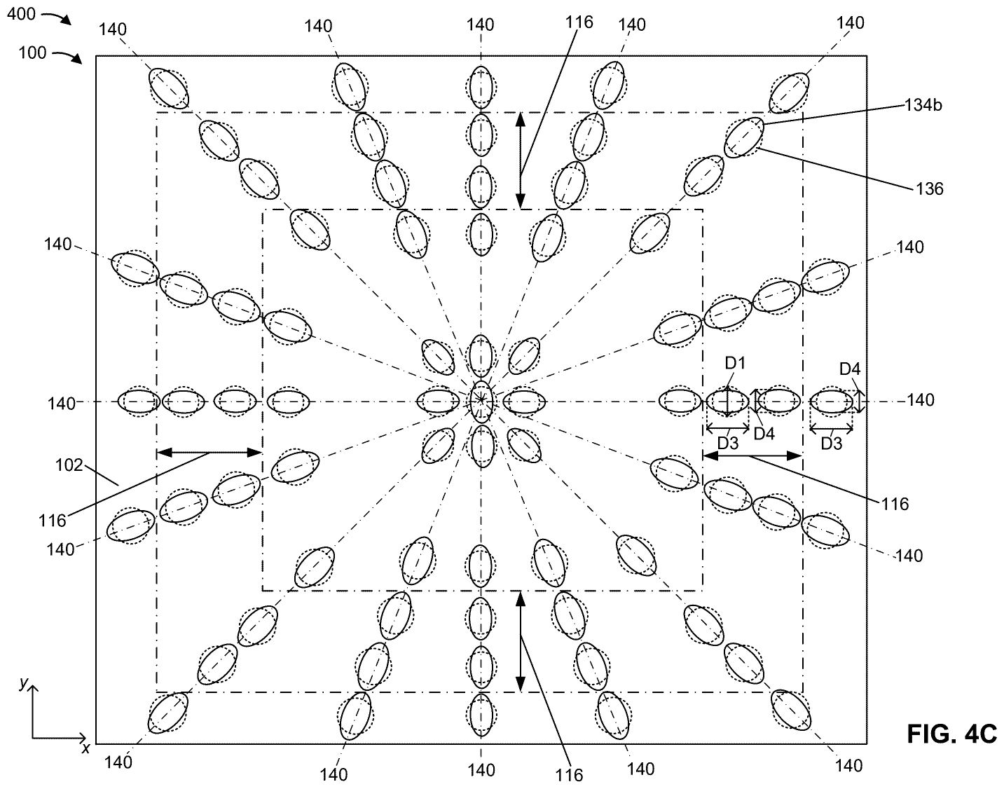

FIGS. 4A-4C are diagrams of an example implementation 400 of the semiconductor package 100. As shown in FIGS. 4A-4C, the semiconductor package 100 may include a similar combination and arrangement of layers and/or structures as illustrated in FIGS. 1A-1C. However, in the example implementation 400, the bottom conductive pads 134a are omitted from the redistribution structure 120a of the package substrate 102 of the semiconductor package 100. Instead, bottom conductive pads 134b are included in the regions of the package substrate 102 outside of the region 116 laterally between the semiconductor die package 104 and the stiffener structure 106.

Thus, and as shown in FIG. 4C, the bottom conductive pads 134b within the region 116 and outside of the region 116 may have lateral widths (dimension D3) along radial axes 140 through the approximate center of the semiconductor package 100 and through an approximate center of the bottom conductive pads 134b that is greater than lateral widths (dimension D4) of the bottom conductive pads 134b in directions approximately perpendicular to the radial axes 140. Accordingly, the bottom conductive pads 134b within the region 116 and outside of the region 116 are elongated in a direction along radial axes 140 through the approximate center of the semiconductor package 100 and through an approximate center of the bottom conductive pads 134b. Including elongated bottom conductive pads 134b under the semiconductor die package 104 and the stiffener structure 106, in addition to the elongated bottom conductive pads 134b located within the region 116 laterally between the semiconductor die package 104 and the stiffener structure 106, may provide further stiffness for the package substrate 102 to further resist bending.

As indicated above, FIGS. 4A-4C are provided as an example. Other examples may differ from what is described with regard to FIGS. 4A-4C.

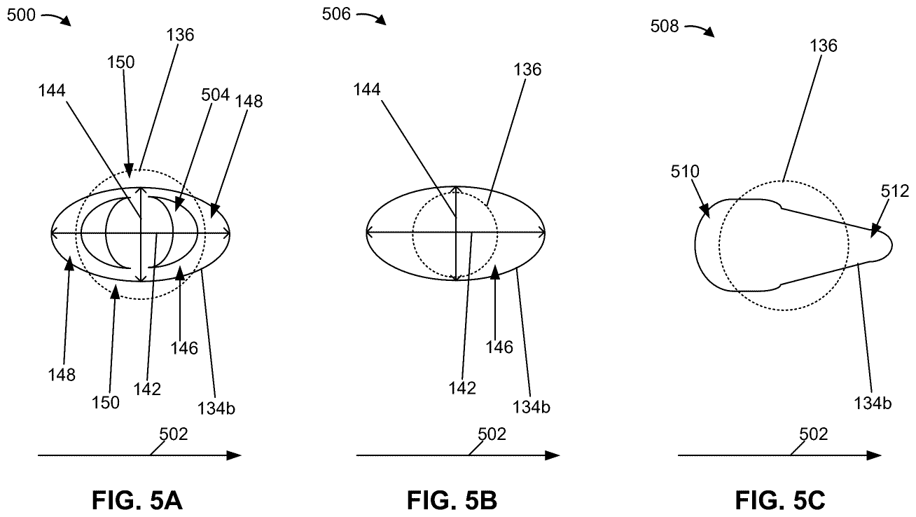

FIGS. 5A-5C are diagrams of examples of bottom conductive pads 134b that may be included in the redistribution structure 120a of the package substrate 102 of the semiconductor package 100 described herein. As shown in FIG. 5A, an example 500 of a bottom conductive pad 134b may be elongated in a radial direction 502 (e.g., along a radial axis 140), and in particular may have an approximate oval top view shape. Moreover, the example 500 of the bottom conductive pad 134b may have holes 504 that are arranged in the radial direction 502 (e.g., along a radius or radial axis 140 of the package substrate 102 through an approximate center of the bottom conductive pad 134b). The holes 504 may facilitate the manufacturing process for the bottom conductive pads 134b of the semiconductor package 100 and may reduce dishing in the bottom conductive pads 134b (e.g., that might otherwise occur during planarization of the bottom conductive pads 134b). The holes 504 may be located in an overlap region 146 where the bottom conductive pad 134b overlaps with a vertically adjacent package connection pad 136.

As shown in FIG. 5B, an example 506 of a bottom conductive pad 134b may be elongated in a radial direction 502 (e.g., along a radial axis 140), and in particular may have an approximate oval top view shape. Moreover, the example 506 of the bottom conductive pad 134b may have a greater width along the major axis 142 of the bottom conductive pad 134b than a vertically adjacent package connection pad 136, as well as a greater width along the minor axis 144 of the bottom conductive pad 134b than a vertically adjacent package connection pad 136. Thus, the bottom conductive pad 134b fully overlaps the package connection pad 136 in the example 506 in FIG. 5B.

As shown in FIG. 5C, an example 508 of a bottom conductive pad 134b may be elongated in a radial direction 502 (e.g., along a radial axis 140). The example 508 of the bottom conductive pad 134b has a non-standard elongated top view shape that includes a rounded section 510 and an elongated section 512 that extends away from the rounded section 510 in the radial direction 502 (e.g., along a radius or radial axis 140 of the package substrate 102 through an approximate center of the bottom conductive pad 134b).

As indicated above, FIGS. 5A-5C are provided as an example. Other examples may differ from what is described with regard to FIGS. 5A-5C. For example, other examples of symmetric elongated top view shapes, asymmetric elongated top view shapes, and/or non-standard elongated top view shapes for the bottom conductive pads 134b of the semiconductor package 100 are within the scope of the present disclosure.

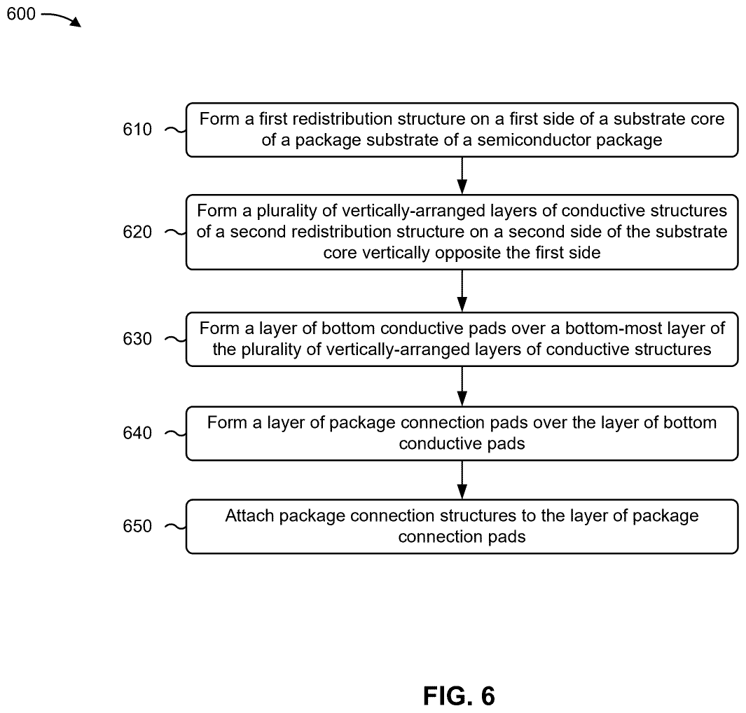

FIG. 6 is a flowchart of an example process 600 associated with forming a semiconductor package described herein. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a first redistribution structure on a first side of a substrate core of a package substrate of a semiconductor package (block 610). For example, one or more semiconductor processing tools may be used to form a first redistribution structure (e.g., a redistribution structure 120b) on a first side of a substrate core (e.g., a substrate core 118) of a package substrate (e.g., a package substrate 102) of a semiconductor package (e.g., a semiconductor package 100), as described herein.

As further shown in FIG. 6, process 600 may include forming a plurality of vertically-arranged layers of conductive structures of a second redistribution structure on a second side of the substrate core vertically opposite the first side (block 620). For example, one or more semiconductor processing tools may be used to form a plurality of vertically-arranged layers of conductive structures (e.g., metallization layers 130a, interconnect layers 132a) of a second redistribution structure (e.g., a redistribution structure 120a) on a second side of the substrate core vertically opposite the first side, as described herein.

As further shown in FIG. 6, process 600 may include forming a layer of bottom conductive pads over a bottom-most layer of the plurality of vertically-arranged layers of conductive structures (block 630). For example, one or more semiconductor processing tools may be used to form a layer of bottom conductive pads (e.g., bottom conductive pads 134, bottom conductive pads 134a, bottom conductive pads 134b) over a bottom-most layer of the plurality of vertically-arranged layers of conductive structures, as described herein. In some implementations, a subset of bottom conductive pads (e.g., bottom conductive pads 134b) of the layer of bottom conductive pads have a top view shape that is elongated in a direction (e.g., a a radial axis 140) along radii of the package substrate through approximate centers of the subset of bottom conductive pads.

As further shown in FIG. 6, process 600 may include forming a layer of package connection pads over the layer of bottom conductive pads (block 640). For example, one or more semiconductor processing tools may be used to form a layer of package connection pads (e.g., package connection pads 136) over the layer of bottom conductive pads, as described herein.

As further shown in FIG. 6, process 600 may include attaching package connection structures to the layer of package connection pads (block 650). For example, one or more semiconductor processing tools may be used to attach package connection structures (e.g., package connection structures 138) to the layer of package connection pads, as described herein.

Process 600 may include additional implementations, such as any single implementation or any combination of implementations described below and/or in connection with one or more other processes described elsewhere herein.

In a first implementation, process 600 includes attaching a stiffener structure (e.g., a stiffener structure 106) to the first redistribution structure, and attaching a semiconductor die package (e.g., a semiconductor die package 104) to the first redistribution structure, where the semiconductor die package is located within a perimeter of the stiffener structure, and where the subset of bottom conductive pads are located around a perimeter of the semiconductor die package in a region (e.g., a region 116) between the semiconductor die package and the stiffener structure.

In a second implementation, alone or in combination with the first implementation, a width (e.g., a dimension D1) of a bottom conductive pad of the subset of bottom conductive pads, along a radius of the package substrate through an approximate center of the bottom conductive pad, is greater than a width of a package connection pad, of the layer of package connection pads, that is vertically adjacent to the bottom conductive pad.

In a third implementation, alone or in combination with one or more of the first and second implementations, a first width of a bottom conductive pad of the subset of bottom conductive pads, along a radius of the package substrate through an approximate center of the bottom conductive pad, is greater than a second width (e.g., dimension D4) of the bottom conductive pad in a second direction that is approximately perpendicular to the radius of the package substrate through the approximate center of the bottom conductive pad.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In this way, a package substrate of a semiconductor package is formed to include bottom conductive pads between package connection pads and conductive structures of the package substrate, where the bottom conductive pads are oblong in a direction along a radial axis through a center of the semiconductor package. The oblong shape and the radial orientation of the bottom conductive pads increase the stiffness of the package substrate, which enables the package substrate to resist deformation that might otherwise occur due to the stresses induced in the package substrate. In this way, the oblong shape and the orientation of the bottom conductive pads reduce the likelihood of cracking and/or delamination in the package substrate that might otherwise be caused by the stresses in the package substrate. Thus, the oblong shape and the orientation of the bottom conductive pads may reduce the likelihood of failure of the semiconductor package and/or may increase the reliability and longevity of the semiconductor package.

As described in greater detail above, some implementations described herein provide a package substrate. The package substrate includes a substrate core that includes a substrate layer. The package substrate includes a first redistribution structure on a first side of the substrate layer and a second redistribution structure on a second side of the substrate layer opposing the first side. The first redistribution structure, the substrate core, and the second redistribution structure are stacked and vertically arranged in the package substrate. The first redistribution structure includes a first insulator layer and a first plurality of conductive structures in the first insulator layer. The second redistribution structure includes a second insulator layer and a second plurality of conductive structures in the second insulator layer. The second redistribution structure also includes a layer of bottom conductive pads vertically adjacent to the second plurality of conductive structures, and a layer of package connection pads vertically adjacent to the layer of bottom conductive pads. At least a subset of bottom conductive pads of the layer of bottom conductive pads have a top view shape that is different from a top view shape of the layer of package connection pads.

As described in greater detail above, some implementations described herein provide a semiconductor package. The semiconductor package includes a package substrate. The semiconductor package includes a stiffener structure attached to the package substrate. The semiconductor package includes a semiconductor die package attached to the package substrate and within a perimeter of the stiffener structure. The package substrate includes a substrate core that includes a substrate layer. The package substrate includes a first redistribution structure on a first side of the substrate layer. The semiconductor die package is attached to the first redistribution structure. The package substrate includes a second redistribution structure on a second side of the substrate layer opposing the first side. The first redistribution structure, the substrate core, and the second redistribution structure are stacked and vertically arranged in the semiconductor package. The first redistribution structure includes a plurality of vertically-arranged layers of conductive structures, a layer of bottom conductive pads vertically adjacent to a bottom-most layer of the plurality of vertically-arranged layers of conductive structures, and a layer of package connection pads vertically adjacent to the layer of bottom conductive pads. A subset of bottom conductive pads of the layer of bottom conductive pads, in a region of the package substrate between the stiffener structure and the semiconductor die package, have a top view shape that is different from a top view shape of the layer of package connection pads. The package substrate includes package connection structures attached to the layer of package connection pads.

As described in greater detail above, some implementations described herein provide a method. The method includes forming a first redistribution structure on a first side of a substrate core of a package substrate of a semiconductor package. The method includes forming a plurality of vertically-arranged layers of conductive structures of a second redistribution structure on a second side of the substrate core vertically opposite the first side. The method includes forming a layer of bottom conductive pads over a bottom-most layer of the plurality of vertically-arranged layers of conductive structures, where a subset of bottom conductive pads of the layer of bottom conductive pads have a top view shape that is elongated in a direction along radii of the package substrate through approximate centers of the subset of bottom conductive pads. The method includes forming a layer of package connection pads over the layer of bottom conductive pads. The method includes attaching package connection structures to the layer of package connection pads.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package substrate, comprising:
a substrate core comprising a substrate layer;
a first redistribution structure, on a first side of the substrate layer, comprising:
a first insulator layer; and
a first plurality of conductive structures in the first insulator layer; and
a second redistribution structure on a second side of the substrate layer opposing the first side,
wherein the first redistribution structure, the substrate core, and the second redistribution structure are stacked and vertically arranged in the package substrate, and
wherein the second redistribution structure comprises:
a second insulator layer; and
a second plurality of conductive structures in the second insulator layer;
a layer of bottom conductive pads vertically adjacent to the second plurality of conductive structures; and
a layer of package connection pads vertically adjacent to the layer of bottom conductive pads,
wherein at least a subset of bottom conductive pads of the layer of bottom conductive pads have a top view shape that is different from a top view shape of the layer of package connection pads.

2. The package substrate of claim 1, wherein a top view shape of a bottom conductive pad, of the at least the subset of bottom conductive pads, is elongated in a radial direction relative to an approximate center of the package substrate.

3. The package substrate of claim 1, wherein a width of a bottom conductive pad, of the at least the subset of bottom conductive pads, in a radial direction relative to an approximate center of the package substrate is greater than a width of a package connection pad, of the layer of package connection pads, that is vertically adjacent to the bottom conductive pad.

4. The package substrate of claim 1, wherein a first width of a bottom conductive pad, of the at least the subset of bottom conductive pads, in a first direction along a radius of the package substrate through an approximate center of the bottom conductive pad is greater than a second width of the bottom conductive pad in a second direction that is approximately perpendicular to the first direction.

5. The package substrate of claim 4, wherein the second width is less than a third width of a package connection pad, of the layer of package connection pads, that is vertically adjacent to the bottom conductive pad.

6. The package substrate of claim 1, wherein opposing portions of a bottom conductive pad, of the at least the subset of bottom conductive pads, extend laterally outward past a package connection pad, of the layer of package connection pads, that is vertically adjacent to the bottom conductive pad; and
wherein the opposing portions extend laterally outward past the package connection pad in a direction along a radius of the package substrate through an approximate center of the bottom conductive pad.

7. The package substrate of claim 6, wherein the bottom conductive pad extend laterally outward past the package connection pad in a direction that is approximately perpendicular to the direction along the radius of the package substrate through the approximate center of the bottom conductive pad.

8. A semiconductor package, comprising:
a package substrate;
a stiffener structure attached to the package substrate; and
a semiconductor die package attached to the package substrate and within a perimeter of the stiffener structure,
wherein the package substrate comprises:
a substrate core comprising a substrate layer;
a first redistribution structure on a first side of the substrate layer,
wherein the semiconductor die package is attached to the first redistribution structure;
a second redistribution structure on a second side of the substrate layer opposing the first side,
wherein the first redistribution structure, the substrate core, and the second redistribution structure are stacked and vertically arranged in the semiconductor package, and
wherein the first redistribution structure comprises:
a plurality of vertically-arranged layers of conductive structures;
a layer of bottom conductive pads vertically adjacent to a bottom-most layer of the plurality of vertically-arranged layers of conductive structures; and
a layer of package connection pads vertically adjacent to the layer of bottom conductive pads,
wherein a subset of bottom conductive pads of the layer of bottom conductive pads, in a region of the package substrate between the stiffener structure and the semiconductor die package, have a top view shape that is different from a top view shape of the layer of package connection pads; and
package connection structures attached to the layer of package connection pads.

9. The semiconductor package of claim 8, wherein a bottom conductive pad of the subset of bottom conductive pads has holes through the bottom conductive pad.

10. The semiconductor package of claim 9, wherein the holes through the bottom conductive pad are located over a package connection pad, of the layer of package connection pads, that is vertically adjacent to the bottom conductive pad.

11. The semiconductor package of claim 9, wherein the holes are arranged in a direction along a radius of the package substrate through an approximate center of the bottom conductive pad.

12. The semiconductor package of claim 8, wherein a bottom conductive pad of the subset of bottom conductive pads comprises:
a rounded section; and
an elongated section that extends away from the rounded section in a direction along a radius of the package substrate through an approximate center of the bottom conductive pad.

13. The semiconductor package of claim 12, wherein a first portion of the rounded section extends laterally outward past a package connection pad, of the layer of package connection pads, that is vertically adjacent to the bottom conductive pad; and
wherein a second portion of the elongated section extends laterally outward past the package connection pad.

14. The semiconductor package of claim 13, wherein the first portion and the second portion extend laterally outward past the package connection pad in the direction along the radius of the package substrate through the approximate center of the bottom conductive pad.

15. The semiconductor package of claim 9, wherein another subset of bottom conductive pads of the layer of bottom conductive pads, in another region of the package substrate under the semiconductor die package, have a top view shape that is different from the top view shape of the layer of package connection pads.

16. The semiconductor package of claim 9, wherein another subset of bottom conductive pads of the layer of bottom conductive pads, in another region of the package substrate under the semiconductor die package, have approximately a same top view shape as the top view shape of the layer of package connection pads.

17. A method, comprising:
forming a first redistribution structure on a first side of a substrate core of a package substrate of a semiconductor package;
forming a plurality of vertically-arranged layers of conductive structures of a second redistribution structure on a second side of the substrate core vertically opposite the first side;
forming a layer of bottom conductive pads over a bottom-most layer of the plurality of vertically-arranged layers of conductive structures,
wherein a subset of bottom conductive pads of the layer of bottom conductive pads have a top view shape that is elongated in a direction along radii of the package substrate through approximate centers of the subset of bottom conductive pads;
forming a layer of package connection pads over the layer of bottom conductive pads; and
attaching package connection structures to the layer of package connection pads.

18. The method of claim 17, further comprising:
attaching a stiffener structure to the first redistribution structure; and
attaching a semiconductor die package to the first redistribution structure,
wherein the semiconductor die package is located within a perimeter of the stiffener structure, and
wherein the subset of bottom conductive pads are located around a perimeter of the semiconductor die package in a region between the semiconductor die package and the stiffener structure.

19. The method of claim 17, wherein a width of a bottom conductive pad of the subset of bottom conductive pads, along a radius of the package substrate through an approximate center of the bottom conductive pad, is greater than a width of a package connection pad, of the layer of package connection pads, that is vertically adjacent to the bottom conductive pad.

20. The method of claim 17, wherein a first width of a bottom conductive pad of the subset of bottom conductive pads, along a radius of the package substrate through an approximate center of the bottom conductive pad, is greater than a second width of the bottom conductive pad in a second direction that is approximately perpendicular to the radius of the package substrate through the approximate center of the bottom conductive pad.
